(19) United States
(12) Patent Application Publication
(10) Pub. No.: US 2008/0291637 A1
(43) Pub. Date: Nov. 27, 2008

(54) SMALL-SIZED COMMUNICATION MODULE PACKAGE

(75) Inventors: Kuan-Hsing Li, Taichung City (TW); Kuo-Hsien Liao, Taichung City (TW)

Correspondence Address: BROWDY AND NEIMARK, P.L.L.C.;624 NINTH STREET, NW, SUITE 300, WASHINGTON, DC, 20001-5303, US

(73) Assignee: Universal Scientific Industrial Co., Ltd., Tsao Tuen (TW)

(21) Appl. No.: 11/943,270

(22) Filed: Nov. 20, 2007

(30) Foreign Application Priority Data
May 22, 2007 (TW) 96208177

(51) Int. Cl. H05K 7/20

(52) U.S. Cl. 361/715

(57) ABSTRACT

A small-sized communication module package mountable on a main board is of stacked structure including a carrier with an opening in which a thermal conductive layer in contact with a substrate stacked on the carrier is filled. The communication module package further includes a chip electrically bonded to the substrate, received in the opening and encapsulated by the thermal conductive layer, and a metal layer in contact with the thermal conductive layer for enhancing heat dissipation.

### BACKGROUND OF THE INVENTION

1. Field of the Invention

The present invention relates generally to a communication module and more particularly, to a small-sized communication module package of stacked structure.

2. Description of the Related Art

A communication module is designed for use in an electronic apparatus to provide a wireless communication function. Following market demands, electronic products, such as cell phones, PDAs and etc., are made having compact and multi-function characteristics. Therefore, modern electronic produces are commonly small-sized. To reduce the size, a conventional communication module package adopts stacked package technology. By means of stacking circuit module(s) on a carrier, a communication module package of stacked structure can be made having compact and multi-function characteristics.

However, when reducing the size of a wireless communication module package, the heat dissipation requirement must be more critical. Conventional package structures for communication module commonly dissipate heat by air. However, the thermal conductivity of air is only about 0.025 W/m·K at room temperature. Because a wireless communication module package is substantially an enclosed structure, it is not in favor of air convection, and heat energy tends to be accumulated inside the package. As a result, conventional communication module packages cannot dissipate heat rapidly, i.e., conventional communication module packages commonly have the drawback of low heat dissipation efficiency. Further, in a conventional communication module package, connections between elements are achieved by means of contact pads only. This connection structure has a weak structural strength. An impact or falling of the communication module package may cause concentration of stress and severe damage.

Therefore it is desirable to provide a small-sized communication module package that can eliminate the aforesaid problems.

### SUMMARY OF THE INVENTION

The present invention has been accomplished under the circumstances in view. It is the primary objective of the present invention to provide a small-sized communication module package, which can provide a good heat dissipation effect and good structural strength.

To achieve the above-mentioned objective, the small-sized communication module package is mountable on a main board and is of stacked structure comprising a carrier with an opening in which a thermal conductive layer in contact with a substrate stacked on the carrier is filled. The communication module package may further includes a chip electrically bonded to the substrate, received in the opening and encapsulated by the thermal conductive layer, and a metal layer in contact with the thermal conductive layer for enhancing heat dissipation.

In a first exemplary embodiment of the present invention to be detailedly described hereinafter, the communication module package comprises a carrier having a top bearing surface, a bottom bearing surface for mounting on the main board, and an opening through the top bearing surface and the bottom bearing surface, and a substrate having a bottom surface electrically bonded to the top bearing surface of the first carrier. A thermal conductive layer formed of an electrically insulative and thermally conductive material is filled up the opening of the first carrier. At least one chip is electrically mounted on the bottom surface of the first substrate, received in the opening of the carrier and encapsulated by the thermal conductive layer. A metal layer is attached to the thermal conductive layer and can be in contact with the main board when the communication module package is mounted on the main board.

In a second exemplary embodiment of the present invention to be detailedly described hereinafter, the communication module package comprises a first carrier, a first substrate, a second carrier and a second substrate stacked one another. The first carrier has an opening in which a first thermal conductive layer is filled and in contact with the first substrate. The second carrier has an opening in which a second thermal conductive layer is filled and in contact with the first and second substrates. The communication module package further comprises at least one chip electrically mounted on the bottom surface of the first substrate, received in the opening of the first carrier and encapsulated by the first thermal conductive, and at least one chip electrically mounted on the top surface of the first substrate, received in the opening of the second carrier and encapsulated by the second thermal conductive layer. A first metal layer is attached to the first thermal conductive layer and can be in contact with the main board when the communication module package is mounted on the main board. A second metal layer is attached to the second thermal conductive layer and in contact with the second substrate.

The small-sized communication module package of the present invention uses an electrically insulative and thermally conductive material for packaging, improving the heat dissipation effect of the communication module and overcoming the drawback of poor heat dissipation effect of the prior art design. Further, the small-sized communication module package can disperse external impact by means of the thermal conductive layer, eliminating concentration of stress and preventing damage to electrically connecting portions of the contact pads. In other words, the small-sized communication module package of the present invention can provide a good structural strength.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic drawing showing the relationship between the substrate and the carrier of a small-sized communication module package in accordance with a first preferred embodiment of the present invention;

FIG. 2 is another schematic drawing showing the substrate and the carrier are bonded together;

FIG. 3 is still another schematic drawing showing that a thermal conductive layer is filled with the opening of the carrier and covers the chips;

FIG. 4 is still another schematic drawing showing that a metal layer is disposed on the thermal conductive layer;

FIG. 5 is a sectional view taken along line 5-5 of FIG. 4;

FIG. 6 is a schematic exploded view showing that the small-sized communication module package according to the first preferred embodiment of the present invention is to be installed on a main board;

FIG. 7 is a schematic perspective assembly view of FIG. 6;

FIG. 8 is a sectional view taken along line 8-8 of FIG. 7; and

FIG. 9 is a sectional view of a small-sized communication module package in accordance with a second preferred embodiment of the present invention.

### DETAILED DESCRIPTION OF THE INVENTION

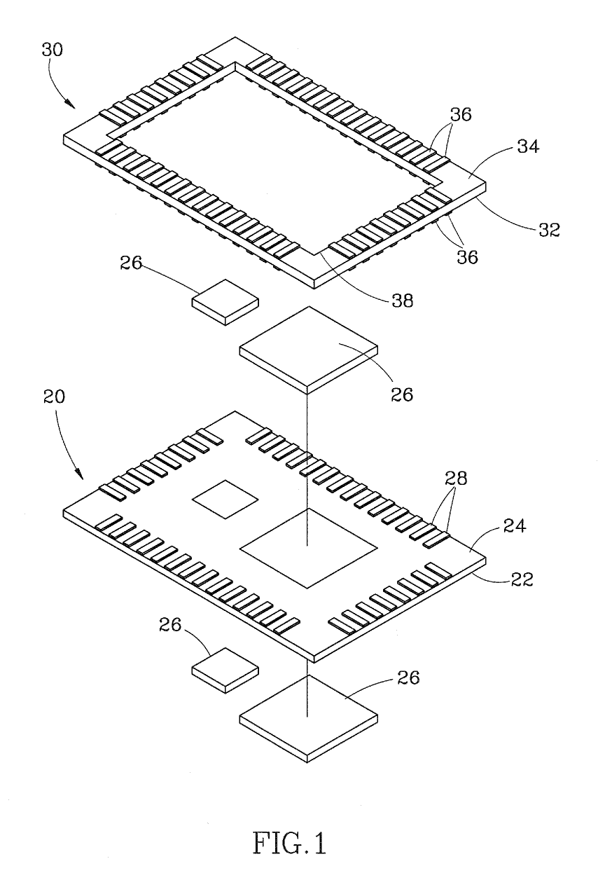

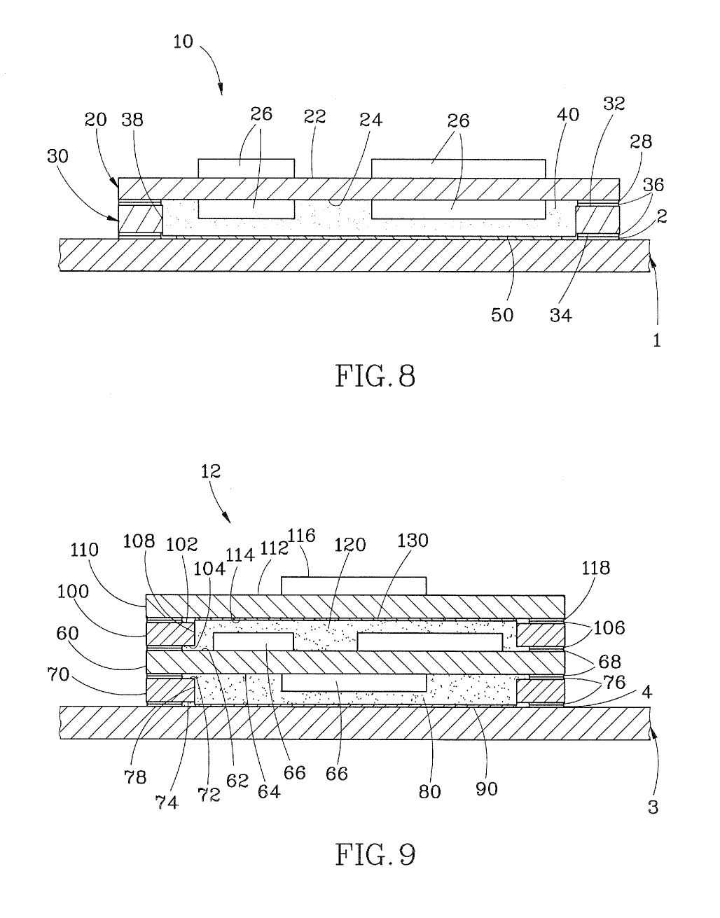

Referring to FIGS. 1-8, a small-sized communication module package 10 in accordance with a first preferred embodiment of the present invention is adapted to be mounted on a main board 1. The communication module package 10 comprises a substrate 20, a carrier 30, a thermal conductive layer 40, and a metal layer 50.

The substrate 20 is made by means of SIP (system-in-package) technology, having a top surface 22, a bottom surface 24 and a plurality of contact pads 28 arranged on the bottom surface 24 around the border of the substrate 20. In this embodiment, two IC chips 26 are respectively mounted on the top surface 22 and the bottom surface 24. It is to be easily understood that the communication module package 10 can be designed containing one or more chips 26 of various functions, which can be mounted on the top surface 22 and/or the bottom surface 24 of the substrate 20 simultaneously or individually, depending on the requirement of the communication module package in practice.

The carrier 30 is stacked on the bottom side of the substrate 20, having a top bearing surface 32, a bottom bearing surface 34, and a plurality of contact pads 36. The contact pads 36 of the carrier 30 are arranged on the top bearing surface 32 and the bottom bearing surface 34 of the carrier 30. The contact pads at the top bearing surface 32 are electrically connected to the contact pads at the bottom bearing surface 34. The contact pads 36 at the top bearing surface 32 are electrically connected to the contact pads 28 at the bottom surface 24 of the substrate 20. The contact pads 36 at the bottom bearing surface 34 are electrically connectable with the contact pads 2 of the main board 1 when the communication module package 10 is mounted on the main board 1. The carrier 30 further has an opening 38 cut through the top bearing surface 32 and the bottom bearing surface 34 for receiving the IC chips 26 at the bottom surface 24 of the substrate 20.

The thermal conductive layer 40 is formed of an electrically insulative and thermally conductive material and filled up the opening 38 of the carrier 30. The thermal conductivity layer 40 is in contact with the bottom surface 24 of the substrate 20 and encapsulates the IC chips 26 at the bottom surface 24 of the substrate 20. The thermal conductive layer 40 has a thermal conductivity greater than 0.2 W/m·K. The thermal conductive layer 40 can be prepared from epoxy resin, silicon resin, silicon-filled epoxy resin, or polyester resin. Preferably, the thermal conductive layer 40 is prepared from epoxy resin that has a thermal conductivity about 0.63 W/m·K.

The metal layer 50 is covered on the free surface of the thermal conductive layer 40 by means of a coating technique and can be closely attachable to the main board 1 when the communication module package 10 is mounted on the main board 1 to enhance the heat dissipation effect of the thermal conductive layer 40.

The method of making the small-sized communication module package 10 according to the first preferred embodiment of the present invention is outlined hereinafter step by step with reference to FIGS. 1-8.

1. At first, apply solder paste on the contact pads 28 at the bottom surface 24 of the substrate 20 and the contact pads 36 at the top bearing surface 32 of the carrier 30 as shown in FIG. 1.

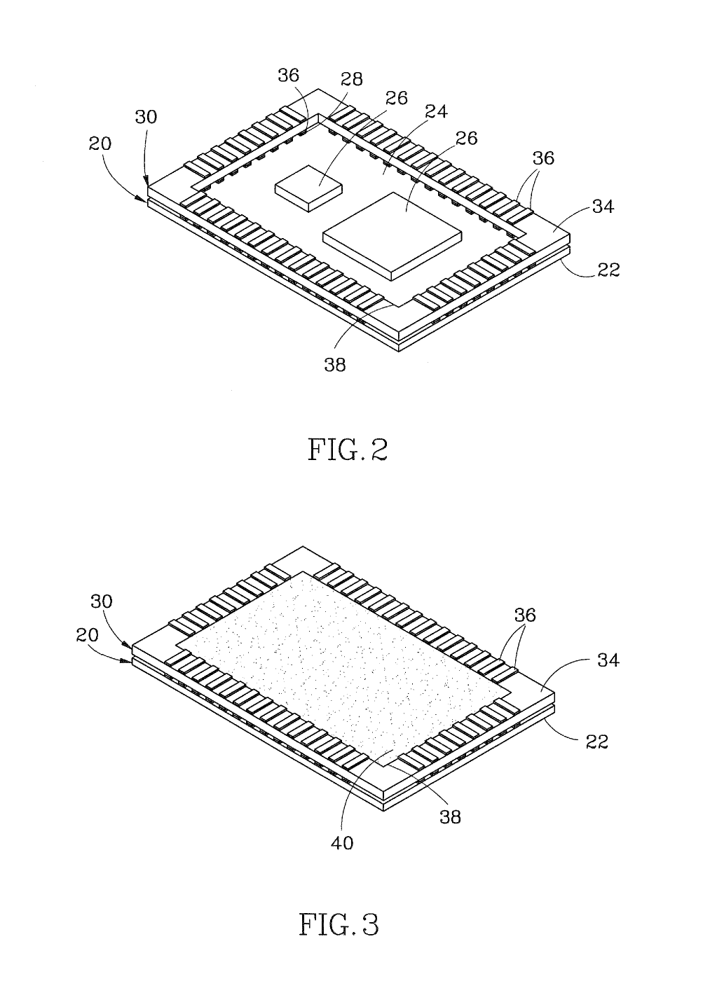

2. Place the carrier 30 on the bottom side of the substrate 20 to attach the contact pads 36 at the top bearing surface 32 of the carrier 30 to the contact pads 28 at the bottom surface 24 of the substrate 20 and to have the IC chips 26 of the substrate 20 be suspended in the opening 38 of the carrier 30, and then heating the applied solder paste to have the carrier 30 and the substrate 20 be bonded together by the solder paste as shown in FIG. 2.

3. Fill up the opening 38 of the carrier 30 with an electrically insulative and thermally conductive material to form the desired thermal conductive layer 40 that is in contact with the bottom surface 24 of the substrate 20 and that encapsulates the IC chips 26 at the bottom surface 24 of the substrate 20 as shown in FIG. 3.

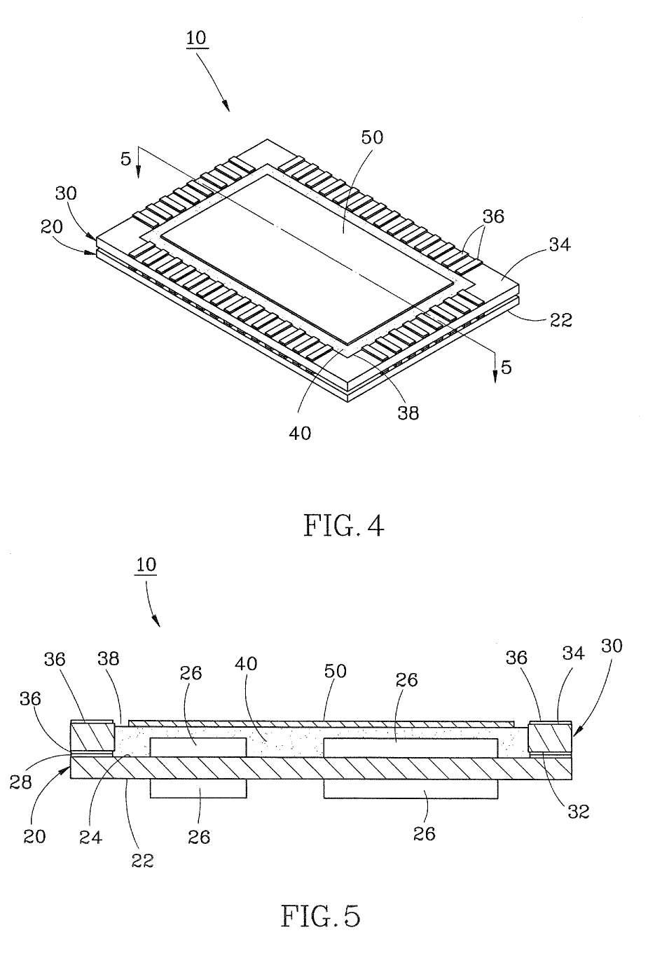

4. Coat the free surface of the thermal conductive layer 40 with a layer of metal material to form the desired metal layer 50, as shown in FIGS. 4 and 5, thereby finishing the small-sized communication module package 10.

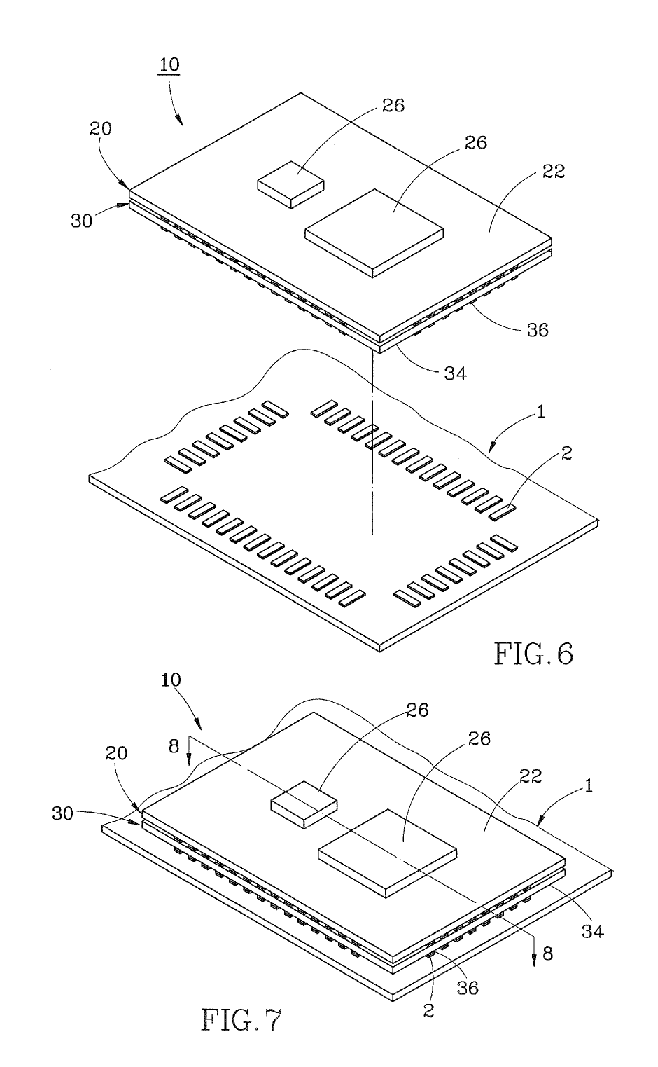

When installing small-sized communication module package 10 on the main board 1, apply solder paste on the contact pads 36 at the bottom bearing surface 34 of the carrier 30 and the contact pads 2 at the main board 1, and then bond the contact pads 36 at the bottom bearing surface 34 of the carrier 30 to the contact pads 2 at the main board 1, as shown in FIGS. 6-8.

According to the aforesaid first preferred embodiment of the present invention, the small-sized communication module package 10 uses an electrically insulative and thermally conductive material, which has a thermal conductivity higher than that of air, to cover the bottom surface 24 of the substrate 20 so as to conduct the heat generated by the substrate 20 to the main board 1 for heat dissipation through the heat-dissipative mechanism (not shown) of the main board 1.

As a result, the thermal conductive layer 40 forms a heat dissipative path in the communication module package 10 to efficiently exhaust the heat generated by the chips 26, improving the heat dissipation efficiency of the communication module package and overcoming the drawback of poor heat dissipation effect of the prior art design. Further, the small-sized communication module package 10 can disperse external impact by means of the connection effect of the thermal conductive layer 40 between the substrate 20 and the carrier 30, eliminating concentration of stress and preventing damage to electrically connecting portions of the contact pads 28, 36. In other words, the communication module package 10 has a characteristic of good structural strength.

FIG. 9 illustrates a small-sized communication module package 12 in accordance with a second preferred embodiment of the present invention, which is installed on a main board 3. The small-sized communication module package 12 comprises a first substrate 60, a first carrier 70, a first thermal conductive layer 80, a first metal layer 90, a second carrier 100, a second substrate 110, a second thermal conductive layer 120, and a second metal layer 130.

The first substrate 60 is made by means of SIP (system-in-package) technology, having a top surface 62, a bottom surface 64 and a plurality of conducting contact pads 68. In this embodiment, an IC chip 66 is mounted on the bottom surface 64 of the first substrate 60, and two IC chips 66 are mounted on the top surface 62 of the first substrate 60. However, it is to be easily understood that the communication module package 12 can be designed containing one or more chips 66 of various functions, which can be mounted on the top surface 62 and/or the bottom surface 64 of the substrate 60 simultaneously or individually, depending on the requirement of the communication module package in practice. The contact pads 68 are respectively arranged on the top surface 62 and bottom surface 64 of the first substrate 60.

The first carrier 70 has a top bearing surface 72, a bottom bearing surface 74, and a plurality of contact pads 76. The contact pads 76 of the first carrier 70 are arranged on the top bearing surface 72 and the bottom bearing surface 74. In addition, the contact pads at the top bearing surface 72 are electrically connected to the contact pads at the bottom bearing surface 74. The contact pads 76 at the top bearing surface 72 are electrically connected to the contact pads 68 of the bottom surface 64 of the first substrate 60. The contact pads 76 at the bottom bearing surface 74 are electrically connected to respective contact pads 4 of the main board 3. The first carrier 70 further has an opening 78 cut through the top bearing surface 72 and the bottom bearing surface 74 for receiving the IC chip 66 at the bottom surface 64 of the first substrate 60.

The first thermal conductive layer 80 is formed of an electrically insulative and thermally conductive material and filled up the opening 78 of the first carrier 70. The thermal conductivity layer 80 is in contact with the bottom surface 64 of the first substrate 60 and encapsulates the IC chips 66 at the bottom surface 64 of the first substrate 60. The first thermal conductive layer 80 has a thermal conductivity greater than 0.2 W/m·K. The first thermal conductive layer 80 may be prepared from epoxy resin, silicon resin, silicon-filled epoxy resin, or polyester resin. Preferably, the first thermal conductive layer 80 is prepared from epoxy resin that has a thermal conductivity about 0.63 W/m·K.

The first metal layer 90 is attached to the free surface of the first thermal conductive layer 80 by a coating technique and can be closely attached to the main board 3 when the communication module package 12 is mounted on the main board 3 to enhance the heat dissipation effect of the first thermal conductive layer 60.

The second carrier 100 has a top bearing surface 102, a bottom bearing surface 104, and a plurality of contact pads 106. The contact pads 106 of the second carrier 100 are respectively arranged on the top bearing surface 102 and bottom bearing surface 104. In addition, the contact pads at the top bearing surface 102 are electrically connected to the contact pads at the bottom bearing surface 104. The contact pads 106 at the bottom bearing surface 104 of the second carrier 100 are electrically connected to the contact pads 68 at the top surface 62 of the first substrate 60. The second carrier 100 further has an opening 108 cut through the top bearing surface 102 and the bottom bearing surface 104 for accommodating the IC chips 66 at the top surface 62 of the first substrate 60.

The second substrate 110 has a top surface 112, a bottom surface 114 and a plurality of contact pads 118. In this embodiment, an IC chip 116 is mounted on the top surface 112 of the second substrate 110. In practice, one or more chips 116 of various functions can be mounted on the top surface 112 and/or the bottom surface 114 of the second substrate 110 simultaneously or individually, depending on the requirement of the communication module package 12. The contact pads 118 of the second substrate 110 are arranged on the bottom surface 114 of the second substrate 110 and electrically connected to the contact pads 106 at the top bearing surface 102 of the second carrier 100.

The second thermal conductive layer 120 is formed of an electrically insulative and thermally conductive material and filled up the opening 108 of the second carrier 100. The second thermal conductive layer 120 is in contact with the top surface 62 of the first substrate 60 and the bottom surface 114 of the second substrate 110 and encapsulates the IC chips 66 at the top surface 62 of the first substrate 60. The second thermal conductive layer 120 has a thermal conductivity greater than 0.2 W/m·K. The second thermal conductive layer 120 can be prepared from epoxy resin, silicon resin, silicon-filled epoxy resin, or polyester resin. Preferably, the second thermal conductive layer 120 is prepared from epoxy resin that has a thermal conductivity about 0.63 W/m·K.

The second metal layer 130 is formed on the second thermal conductive layer 120 by a coating technique and closely attached to the bottom surface 114 of the second substrate 110 to enhance the heat dissipation effect of the second thermal conductive layer 120.

According to the aforesaid second preferred embodiment of the present invention, the small-sized communication module package 12 uses an electrically insulative and thermally conductive material, which has a thermal conductivity higher than that of air, to cover the bottom surface 64 and the top surface 62 of the first substrate 60 so as to conduct the heat generated by the first substrate 60 and second substrate 110 to the main board 3 through the first metal layer 90 and second metal layer 130 for heat dissipation through the heat-dissipative mechanism (not shown) of the main board 3.

As a result, the thermal conductive layers 80, 120 form a heat dissipative path in the communication module package 12 to efficiently exhaust the heat generated by the chips 66, 116, improving the heat dissipation efficiency of the communication module package and overcoming the drawback of poor heat dissipation effect of the prior art design. Further, the small-sized communication module package 12 can disperse external impact by means of the connection effects of the thermal conductive layers 80, 120 between the substrates 60, 110 and the carriers 70, 100, eliminating concentration of stress and preventing damage to electrically connecting portions of the contact pads 68, 76, 106. In other words, the communication module package 12 has a characteristic of good structural strength.

In conclusion, the present invention provides a small-sized communication module package, which uses an electrically insulative and thermally conductive material for packaging, improving the heat dissipation efficiency of the communication module package and overcoming the drawback of poor heat dissipation effect of the prior art design. Further, the small-sized communication module package can disperse external impact by means of the thermal conductive layer(s), eliminating concentration of stress and preventing damage to electrically connecting portions of the contact pads.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A small-sized communication module package mountable on a main board, the communication module package comprising:
a first carrier having a top bearing surface, a bottom bearing surface for mounting on the main board, and an opening through the top bearing surface and the bottom bearing surface;
a first substrate having a top surface and a bottom surface electrically bonded to the top bearing surface of the first carrier; and
a first thermal conductive layer formed of an electrically insulative and thermally conductive material and filled up the opening of the first carrier.

2. The small-sized communication module package as claimed in claim 1, wherein the first thermal conductive layer has a thermal conductivity greater than 0.2 W/m·K.

3. The small-sized communication module package as claimed in claim 1, wherein the first thermal conductive layer is made by a material selected from the group consisting of epoxy resin, silicon resin, silicon-filled epoxy resin and polyester resin.

4. The small-sized communication module package as claimed in claim 1, wherein the first thermal conductive layer is in contact with the bottom surface of the first substrate.

5. The small-sized communication module package as claimed in claim 1, further comprising a metal layer in contact with the first thermal conductive layer.

6. The small-sized communication module package as claimed in claim 1, wherein the first substrate is provided on the bottom surface thereof with a plurality of contact pads, and the first carrier is provided with a plurality of contact pads on the top bearing surface and the bottom bearing surface respectively; the contact pads on the top bearing surface of the first carrier are electrically bonded to the contact pads of the first substrate, and the contact pads on the bottom bearing surface of the first carrier are for electrical connection with the main board.

7. The small-sized communication module package as claimed in claim 1, further comprising at least one chip mounted on one of the top and bottom surfaces of the first substrate.

8. The small-sized communication module package as claimed in claim 7, wherein the at least one chip includes a chip electrically mounted on the bottom surface of the first substrate, received in the opening of the first carrier and encapsulated by the first thermal conductive layer.

9. The small-sized communication module package as claimed in claim 1, further comprising:
a second carrier having a top bearing surface, a bottom bearing surface electrically bonded to the top surface of the first substrate, and an opening through the top bearing surface and bottom bearing surface thereof;
a second substrate having a top surface, a bottom surface electrically bonded to the top bearing surface of the second carrier; and
a second thermal conductive layer formed of an electrically insulative and thermally conductive material and filled up the opening of the second carrier.

10. The small-sized communication module package as claimed in claim 9, wherein the first thermal conductive layer and the second thermal conductive layer have a thermal conductivity greater than 0.2 W/m·K.

11. The small-sized communication module package as claimed in claim 9, wherein the first thermal conductive layer and the second thermal conductive layer are made by a material selected from the group consisting of epoxy resin, silicon resin, silicon-filled epoxy resin and polyester resin.

12. The small-sized communication module package as claimed in claim 9, wherein the first thermal conductive layer is in contact with the bottom surface of the first substrate.

13. The small-sized communication module package as claimed in claim 9, wherein the second thermal conductive layer is in contact with top surface of the first substrate and the bottom surface of the second substrate.

14. The small-sized communication module package as claimed in claim 9, further comprising at least one metal layer in contact with one of the first thermal conductive layer and the second thermal conductive layer.

15. The small-sized communication module package as claimed in claim 14, wherein the at least one metal layer includes a first metal layer in contact with the first thermal conductive layer.

16. The small-sized communication module package as claimed in claim 14, wherein the at least one metal layer includes a second metal layer in contact with the second thermal conductive layer and the second substrate.

17. The small-sized communication module package as claimed in claim 9, wherein the first substrate has a plurality of contact pads arranged on the top surface and the bottom surface thereof for electrical connection; the second substrate comprises a plurality of contact pads arranged on the bottom surface thereof for electrical connection; the first carrier and the second carrier each have a plurality of contact pads arranged on the respective top bearing surface and bottom bearing surface for electrical connection.

18. The small-sized communication module package as claimed in claim 9, further comprising at least one chip mounted on one of the top and bottom surfaces of the first substrate, and at least one chip mounted on one of the top and bottom surfaces of the second substrate.

19. The small-sized communication module package as claimed in claim 18, wherein the at least one chip that is mounted on one of the top and bottom surfaces of the first substrate includes a chip electrically mounted on the bottom surface of the first substrate, received in the opening of the first carrier and encapsulated by the first thermal conductive layer.

20. The small-sized communication module package as claimed in claim 18, wherein the at least one chip that is mounted on one of the top and bottom surfaces of the first substrate includes a chip electrically mounted on the top surface of the first substrate, received in the opening of the second carrier and encapsulated by the second thermal conductive layer.
